(19) United States
(12) Patent Application Publication
(10) Pub. No.: US 2021/0328195 A1
(43) Pub. Date: Oct. 21, 2021

(54) DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Hanning YANG, Wuhan, Hubei (CN)

(21) Appl. No.: 16/492,392

(22) PCT Filed: Aug. 7, 2019
(86) PCT No.: PCT/CN2019/099601

§ 371 Date: Sep. 9, 2019

(30) Foreign Application Priority Data
May 13, 2019 (CN) 201910415538.1

(51) Int. Cl. H01L 51/52; H01L 27/32; G02B 5/30

(52) U.S. Cl. CPC H01L 51/5281; G02B 5/3083; G02B 5/3016; H01L 27/323

(57) ABSTRACT

A display device is disclosed and includes a display panel, a circular polarization cover disposed over the display panel, and a polarization module disposed between the display panel and the circular polarization cover, wherein light emitted from the display panel toward the polarization module is formed into circularly polarized light or elliptically polarized light via the circular polarization cover.

### FIELD OF INVENTION

The present disclosure relates to the technical field of display structures, and specifically to a display device that can emit circularly polarized light.

### BACKGROUND OF INVENTION

With development of display technology, people increasingly use displays such as liquid crystal displays (LCDs) or organic light emitting diode (OLED) displays. Thus, impact of a display screen on human eye health is getting more and more attention.

For example, as shown in FIG. 1, current OLED display 9 includes an OLED panel 91, a polarizer 92, and a cover 93. The polarizer 92 can convert light R1 emitted from the OLED panel 91 into linearly polarized light LP. However, the cover 93 is usually a glass made of inorganic materials. Light passing through the cover 93 does not change polarization characteristics, such that long-term viewing of the human eye leads to fatigue easily. In order to solve this problem, techniques have been developed to add a 214 phase retardation sheet, but the 214 phase retardation sheet increased will increase a thickness of the display.

In addition, when users wear sunglasses, since the sunglasses are also made of a linear polarizer, when a light transmitting axial direction of the sunglasses is perpendicular to a light emitting axis of the OLED display screen, users wearing the sunglasses cannot watch images on the OLED display screen.

Therefore, display technology in the prior art has defects and needs to improve urgently.

### SUMMARY OF INVENTION

In view of the above description, the present disclosure provides a display device to solve a problem that reflected light of the display screen in the prior art is linearly polarized light.

In order to achieve the above object, an embodiment of the present disclosure provides a display device, which includes a display panel; a circular polarization cover disposed over the display panel; a polarization module disposed between the display panel and the circular polarization cover, wherein the polarization module comprises a circular polarizer and a linear polarizer disposed between the circular polarizer and the circular polarization cover; and a touch module disposed on the display panel, the polarization module, or the circular polarization cover; wherein light emitted from the display module toward the polarization module is formed into circularly polarized light or elliptically polarized light via the circular polarization cover.

In an embodiment of the present disclosure, the circular polarization cover is a glass cover containing crystal or ceramic with a birefringence effect.

In an embodiment of the present disclosure, the circular polarization cover consists of silicon dioxide and ions selected from the group consisting of bismuth, strontium, and barium ions.

In an embodiment of the present disclosure, the circular polarization cover is made of colorless polyimide by doping anisotropic molecules or orienting molecular chains of the colorless polyimide in a same direction.

In an embodiment of the present disclosure, the circular polarization cover has a phase retardation layer.

In an embodiment of the present disclosure, the phase retardation layer is a liquid crystal layer.

In an embodiment of the present disclosure, material of the phase retardation layer is precious metal material or graphene.

In an embodiment of the present disclosure, the phase retardation layer is provided with a decorative film and is disposed on a covering layer; and the covering layer is a glass containing silicon dioxide or a cover made of colorless polyimide.

In order to achieve the above object, another embodiment of the present disclosure provides a display device, which includes a display panel; a circular polarization cover disposed over the display panel; and a polarization module disposed between the display panel and the circular polarization cover; wherein light emitted from the display module toward the polarization module is formed into circularly polarized light or elliptically polarized light via the circular polarization cover.

In an embodiment of the present disclosure, the circular polarization cover is a glass cover containing crystal or ceramic with a birefringence effect.

In an embodiment of the present disclosure, the circular polarization cover consists of silicon dioxide and ions selected from the group consisting of bismuth, strontium, and barium ions.

In an embodiment of the present disclosure, the circular polarization cover is made of colorless polyimide by doping anisotropic molecules or orienting molecular chains of the colorless polyimide in a same direction.

In an embodiment of the present disclosure, the circular polarization cover has a phase retardation layer.

In an embodiment of the present disclosure, the phase retardation layer is a liquid crystal layer.

In an embodiment of the present disclosure, material of the phase retardation layer is precious metal material or graphene.

In an embodiment of the present disclosure, the phase retardation layer is provided with a decorative film.

In an embodiment of the present disclosure, the phase retardation layer is disposed on a covering layer.

In an embodiment of the present disclosure, the covering layer is a glass containing silicon dioxide or a cover made of colorless polyimide.

In an embodiment of the present disclosure, the polarization module comprises a circular polarizer and a linear polarizer disposed between the circular polarizer and the circular polarization cover.

In an embodiment of the present disclosure, the display device further includes a touch module disposed on the display panel, the polarization module, or the circular polarization cover.

Compared with the prior art, the display device of the present disclosure can convert light from the display panel into circularly polarized light via the circular polarization cover, such that display users are not affected by linearly polarized light and are not easy to cause eye fatigue. Meanwhile, display users can avoid from being affected by sunglasses. In addition, the circular polarization cover can directly replace the current glass to be a cover of the display device. The display device does not need to add a phase retardation sheet to have a circular polarization function. Thus, it can prevent the phase retardation sheet from causing an increase in thickness of the display device.

### BRIEF DESCRIPTION OF DRAWINGS

FIG. 1 is a schematic diagram of an organic light emitting diode (OLED) display screen in the prior art.

FIG. 2 is a schematic diagram of a display device of a first embodiment according to the present disclosure.

FIG. 3 is a schematic diagram illustrating a polarization conversion of the display device of the first embodiment according to the present disclosure.

FIG. 4 is a schematic diagram illustrating an anti-reflection of the display device of the first embodiment according to the present disclosure.

FIG. 5 is a schematic diagram of a display device of a second embodiment according to the present disclosure.

### DETAILED DESCRIPTION OF PREFERRED EMBODIMENTS

Following a description of the various embodiments refers to additional drawings for illustrating specific embodiments of the present disclosure. Furthermore, directional terms mentioned in the present disclosure, such as upper, lower, top, bottom, front, rear, left, right, inner, outer, side, surrounding, central, horizontal, lateral, vertical, longitudinal, axial, radial, uppermost or lowermost, etc., which only refer to the direction of drawings. Therefore, the directional terms used as above are for the purpose of illustration and understanding of the present disclosure, and are not intended to limit the present disclosure.

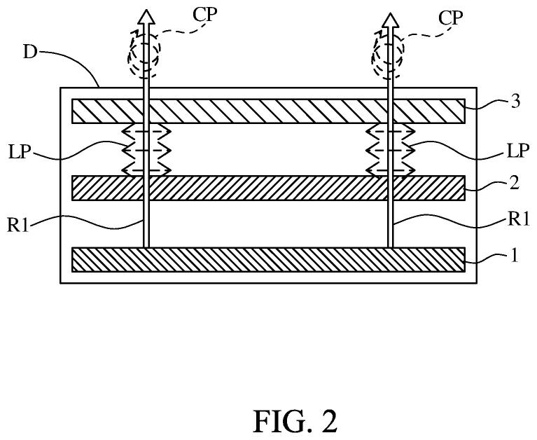

Please refer to FIG. 2, a display device D of a first embodiment of the present disclosure may include a display panel 1, a polarization module 2, and a circular polarization cover 3. The circular polarization cover 3 is disposed over the display panel 1. The polarization module 2 is disposed between the display panel 1 and the circular polarization cover 3, wherein light emitted from the display module 1 toward the polarization module 2 is formed into circularly polarized light or elliptically polarized light via the circular polarization cover 3. The above display device is exemplified as below, but is not limited thereto.

For example, in an embodiment, as shown in FIG. 2, the display panel may be an organic light emitting diode (OLED) display panel, a liquid crystal (LC) display panel, or the likes. The display panel 1 can emit light R1 toward the polarization module 2. The light R1 may be formed into linearly polarized light (e.g., LP) via the polarization module 2. The linearly polarized light may be formed into circularly polarized light (e.g., CP) or elliptically polarized light via the circular polarization cover 3. To continue, a proceeding illustration is exemplified by taking an example of converting light of the OLED display panel into circularly polarized light, but is not limited thereto, related description is also applied to the liquid crystal display panel and elliptically polarized light.

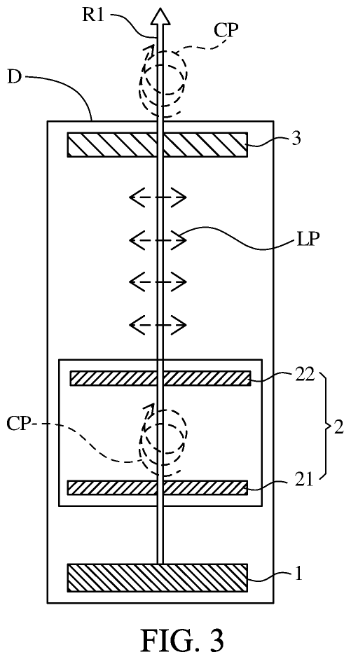

In an embodiment, as shown in FIG. 3, the polarization module 2 includes a circular polarizer 21 and a linear polarizer 22 disposed between the circular polarizer 21 and the circular polarization cover 3. For example, the circular polarizer 21 may be a 214 phase retardation sheet, such that light emitted from the display panel can be converted into circularly polarized light CP via the circular polarizer 21 within the polarization module 2. The circularly polarized light CP can be converted into linearly polarized light LP via the linear polarizer 22 within the polarization module 2. The linearly polarized light LP can be converted into circularly polarized light CP via the circular polarization cover 3 with a circular polarizing function.

In an embodiment, as shown in FIGS. 2 and 3, the circular polarization cover 3 may be a glass cover containing crystal or ceramic with a birefringence effect. For example, the circular polarization cover 3 is made of a crystal having the birefringence effect (e.g., anisotropic crystals, such as calcite, quartz, or ruby) or a ceramic having the birefringence effect (such as a fine-grained transparent ferroelectric ceramic having a grain size of about 1 to 2 μm) instead of silicon dioxide (SiO₂). A phase retardation coefficient of the circular polarization cover 3 can be adjusted by designing a thickness of the circular polarization cover 3, so that the circular polarization cover 3 has a λ/4 phase retardation function. Thus, since physical properties of the above crystal or ceramic are close to physical properties of silicon dioxide, the circular polarization cover 3 has a circular polarization function and the same physical characteristics as the conventional glass cover.

Alternatively, as shown in FIGS. 2 and 3, in an embodiment, the circular polarization cover 3 may consist of silicon dioxide and ions selected from the group consisting of bismuth, strontium, and barium ions. For example, regarding the glass cover made of the conventional silicon dioxide, metal ions in the glass are diffused and exchanged with metal ions in molten salt at a melting temperature of the glass cover. Ion implantation can be implemented by controlling the time of ion exchange in different regions. The ions commonly used for the ion implantation include bismuth, strontium, or barium ions. Therefore, refractive index of the silicon dioxide is changed by implanting the above ions, thereby forming a refractive index of a material being anisotropic. The λ/4 phase retardation function can be implemented by adjusting a phase difference.

Alternatively, as shown in FIGS. 2 and 3, in an embodiment, the circular polarization cover 3 may be made of colorless polyimide (CPI) by doping anisotropic molecules or orienting molecular chains of the colorless polyimide in a same direction. For example, for the circular polarization cover 3 made of the organic materials such as CPI, in a preparing process of organic materials such as CPI, an organic thin film having the birefringence effect may be obtained by doping the other organic material having anisotropic molecules (such as liquid crystal molecules) or orienting molecular chains of the organic material in the same direction (such as applying an external force in an axial direction to orient the molecular chain in one direction). Therefore, the circular polarization cover 3 having the circular polarization function and made of the organic material can be achieved by adjusting an orientation of the molecular chain and a length of the molecular chain.

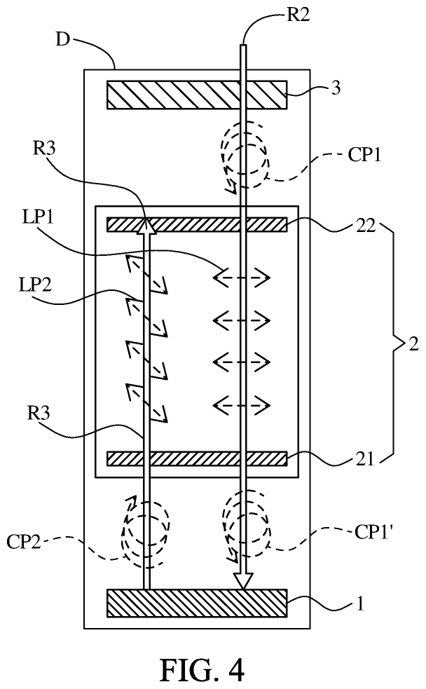

In addition, as shown in FIG. 4, the above display device D also has a conventional anti-reflection function. For example, external ambient incident light R2 is converted into circularly polarized light CP1 via the circular polarization cover 3 having the circular polarization function. The circularly polarized light CP1 is converted into linearly polarized light LP1 via the linear polarizer 22 within the polarization module 2. Polarization directions of the linearly polarized light LP1 and the linear polarizer 22 are parallel to each other. The linearly polarized light LP1 is converted into right-handed circularly polarized light CP1′ via the circular polarizer 21 within the polarization module 2. The right-handed circularly polarized light CP1′ is reflected into left-handed circularly polarized light CP2 by a reflection film within the display panel 1 (such as a metal layer within the OLED display panel). The left-handed circularly polarized light CP2 is converted into linearly polarized light LP2 via the circular polarizer 21 within the polarization module 2. Polarization directions of the linearly polarized light LP2 and the linear polarizer 22 are perpendicular to each other, so that the linearly polarized light LP2 cannot pass through the linear polarizer 22. Therefore, light R3 generated after a reflection of the external ambient incident light R2 cannot emit from the circular polarization cover 3, thereby achieving an anti-reflection function.

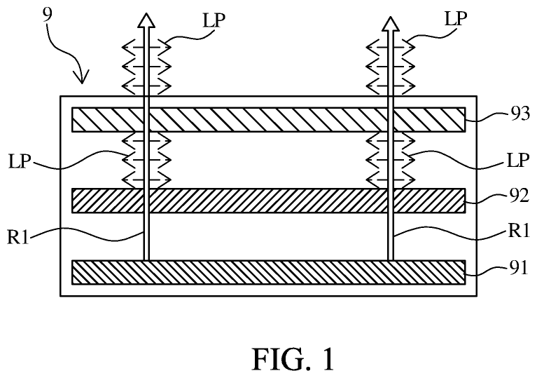

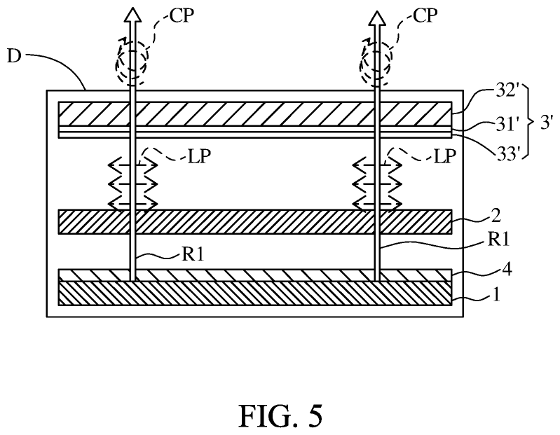

In addition, as shown in FIGS. 1 and 5, a difference between a second embodiment and the first embodiment of the present disclosure is mainly that, structures of the circular polarization cover are different, but other structures are the same, which are not described again. As shown in FIG. 5, in the second embodiment, the circular polarization cover 3′ has a phase retardation layer 31′. For example, the phase retardation layer 31′ may be disposed toward the polarization module 2. A material of the phase retardation layer 31′ may be a liquid crystal layer, such as using twisted nematic liquid crystal with birefringence properties. By adjusting a thickness of the liquid crystal layer and an orientation of the liquid crystal, the liquid crystal layer can also function as the phase retardation layer 31′ having a ¼ wavelength.

In an embodiment, as shown in FIG. 5, the phase retardation layer 31′ may further be disposed on a covering layer 32′. The covering layer 32′ may be a glass containing silicon dioxide or a cover made of colorless polyimide. Thus, a substrate having the phase retardation layer 31′ can be easily obtained to reduce manufacturing cost.

In an embodiment, as shown in FIG. 5, material of the phase retardation layer 31′ may be precious metal material (such as gold or platinum) or graphene. For example, the material such as the precious metal or graphene is processed under the covering layer 32′ by physical etching or chemical modification to form a metamaterial having an anisotropy of refractive index. The circular polarization function can also be realized by adjusting a shape and a size of the metamaterial.

In an embodiment, as shown in FIG. 5, the phase retardation layer 31′ is provided with a decorative film (Deco film) 33′. Taking the above liquid crystal layer as an example, the decorative film 33′ may be coated under the liquid crystal layer, such that the decorative film 33′ can serve as an orientation layer and a protective film of the liquid crystal. In addition, taking the above metamaterial as an example, the decorative film 33′ may be coated under the metamaterial, such that the decorative film 33′ can serve as a protective layer for the metamaterial, thereby increasing product life.

In an embodiment, as shown in FIG. 5, the display device D may further provide with a touch module 4. For example, the touch panel 4 may be disposed on the display panel 1, but is not limited thereto. Alternatively, the touch panel 4 may be disposed on the polarization module 2 or the circular polarization cover 3, such that the display device of the above first and second embodiments may further have a touch function.

It should be noted that, as shown in FIGS. 2 to 5, a plurality of gaps between the display panel 1, the polarization module 2, and the circular polarization cover 3 in the display device of the present disclosure are used to explain the above embodiments, the display panel 1, the polarization module 2 and the circular polarization cover 3 can actually be brought into close or contact with each other, or directly or indirectly combined as needed.

It should be noted that, the display device of the present disclosure can be changed based on implementation requirements. For example, the display device can be applied to a desktop display, a smart phone, a tablet computer, a notebook computer, or a smart watch, etc.

Compared with the prior art, the display device of the present disclosure can convert light from the display panel into circularly polarized light via the circular polarization cover, such that display users are not affected by linearly polarized light and are not easy to cause eye fatigue. Meanwhile, display users can avoid from being affected by sunglasses. In addition, the circular polarization cover can directly replace the current glass to be a cover of the display device. The display device does not need to add a phase retardation sheet to have a circular polarization function. Thus, it can prevent the phase retardation sheet from causing an increase in thickness of the display device.

It is understood that, for clarity, specific features of the present disclosure are described in the context of separate embodiments and may be provided in a combination of a single embodiment. Conversely, in the present disclosure, various features described in the context of a single embodiment may also be separated, or in any suitable sub-combination, or described in any other embodiments of the present disclosure. The specific features described in the context of the various embodiments are not considered to be essential features of those embodiments, unless that the embodiments do not have function without those elements.

Singular forms “a”, “an”, and “at least one” used herein include plural references, unless clearly specifies otherwise.

Although the present disclosure is described in connection with specific embodiments thereof, many alternatives, modifications, and changes will be obvious to those skilled in the art. Therefore, it is intended to include all substitutions, modifications, and changes falling within a scope of appended claims.

1. A display device, comprising:
a display panel;
a circular polarization cover disposed over the display panel;
a polarization module disposed between the display panel and the circular polarization cover, wherein the polarization module comprises a circular polarizer and a linear polarizer disposed between the circular polarizer and the circular polarization cover; and
a touch module disposed on the display panel, the polarization module, or the circular polarization cover;
wherein light emitted from the display panel toward the polarization module is formed into circularly polarized light or elliptically polarized light via the circular polarization cover.

2. The display device as claimed in claim 1, wherein the circular polarization cover is a glass cover containing crystal or ceramic with birefringence effect.

3. The display device as claimed in claim 1, wherein the circular polarization cover consists of silicon dioxide and ions selected from the group consisting of bismuth, strontium, and barium ions.

4. The display device as claimed in claim 1, wherein the circular polarization cover is made of colorless polyimide having doped anistropic molecules or colorless polymide having molecular chains oriented in a same direction.

5. The display device as claimed in claim 1, wherein the circular polarization cover has a phase retardation layer.

6. The display device as claimed in claim 5, wherein the phase retardation layer is a liquid crystal layer.

7. The display device as claimed in claim 5, wherein material of the phase retardation layer is precious metal material or graphene.

8. The display device as claimed in claim 5, wherein the phase retardation layer is provided with a decorative film and is disposed on a covering layer; and the covering layer is a glass containing silicon dioxide or a cover made of colorless polyimide.

9. A display device, comprising:
a display panel;
a circular polarization cover disposed over the display panel; and
a polarization module disposed between the display panel and the circular polarization cover;
wherein light emitted from the display panel toward the polarization module is formed into circularly polarized light or elliptically polarized light via the circular polarization cover.

10. The display device as claimed in claim 9, wherein the circular polarization cover is a glass cover containing crystal or ceramic with birefringence effect.

11. The display device as claimed in claim 9, wherein the circular polarization cover consists of silicon dioxide and ions selected from the group consisting of bismuth, strontium, and barium ions.

12. The display device as claimed in claim 9, wherein the circular polarization cover is made of colorless polyimide having doped anistropic molecules or colorless polymide having molecular chains oriented in a same direction.

13. The display device as claimed in claim 9, wherein the circular polarization cover has a phase retardation layer.

14. The display device as claimed in claim 13, wherein the phase retardation layer is a liquid crystal layer.

15. The display device as claimed in claim 13, wherein material of the phase retardation layer is precious metal material or graphene.

16. The display device as claimed in claim 13, wherein the phase retardation layer is provided with a decorative film.

17. The display device as claimed in claim 13, wherein the phase retardation layer is disposed on a covering layer.

18. The display device as claimed in claim 17, wherein the covering layer is a glass containing silicon dioxide or a cover made of colorless polyimide.

19. The display device as claimed in claim 9, wherein the polarization module comprises a circular polarizer and a linear polarizer disposed between the circular polarizer and the circular polarization cover.

20. The display device as claimed in claim 9, further comprising a touch module disposed on the display panel, the polarization module, or the circular polarization cover.
